(19) United States
(12) Patent Application Publication
(10) Pub. No.: US 2025/0393265 A1
(43) Pub. Date: Dec. 25, 2025

(54) STRESSED NANOSHEET CHANNELS

(71) Applicant: International Business Machines Corporation, Armonk, NY (US)

(72) Inventors: Mohamed Abdelmaksoud Mohamed Rabie, Clifton Park, NY (US); Karsu Kilic, Palo Alto, CA (US); Dureseti Chidambarrao, Weston, CT (US)

(21) Appl. No.: 18/751,616

(22) Filed: Jun. 24, 2024

(51) Int. Cl. H01L 29/06; H01L 27/092; H01L 29/08; H01L 29/423; H01L 29/775; H01L 29/786

(52) U.S. Cl. CPC H10D 62/121; H10D 30/43; H10D 30/6735; H10D 30/6757; H10D 62/151; H10D 84/85

(57) ABSTRACT

A semiconductor structure includes a substrate, two or more nanosheet channel layers disposed over a first portion of the substrate, and a source/drain region disposed over a second portion of the substrate adjacent the first portion of the substrate. The source/drain region is a crystalline semiconductor material which transfers a longitudinal stress to the two or more nanosheet channel layers.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of Silicon Germanium (SiGe), between sheets of channel material, which may be formed of Silicon (Si).

### SUMMARY

Embodiments of the invention provide techniques for forming semiconductor structures with stressed nanosheet channels.

In one embodiment, a semiconductor structure includes a substrate, two or more nanosheet channel layers disposed over a first portion of the substrate, and a source/drain region disposed over a second portion of the substrate adjacent the first portion of the substrate. The source/drain region is a crystalline semiconductor material which transfers a longitudinal stress to the two or more nanosheet channel layers.

In another embodiment, a semiconductor structure includes a substrate, two or more nanosheet channel layers disposed over a first portion of the substrate, a first source/drain region disposed over a second portion of the substrate adjacent a first side of the first portion of the substrate, and a second source/drain region disposed over a third portion of the substrate adjacent a second side of the first portion of the substrate, where the first source/drain region and the second source/drain region provide a stressor material which transfers a longitudinal stress to the two or more nanosheet channel layers.

In another embodiment, an integrated circuit includes a semiconductor structure including a substrate, two or more nanosheet channel layers disposed over a first portion of the substrate, and a source/drain region disposed over a second portion of the substrate adjacent the first portion of the substrate. The source/drain region is a crystalline semiconductor material which transfers a longitudinal stress to the two or more nanosheet channel layers.

### BRIEF DESCRIPTION OF THE DRAWINGS

FIG. 1 shows a semiconductor structure with nanosheet channel layers, according to an embodiment of the invention.

FIG. 2A shows a cross-sectional view of a semiconductor structure following initial epitaxial growth of source/drain regions templating from exposed surfaces of a substrate and nanosheet channel layers, according to an embodiment of the invention.

FIG. 2B shows a cross-sectional view of the FIG. 2A structure following continued epitaxial growth of the source/drain regions and formation of stacking faults, according to an embodiment of the invention.

FIG. 2C shows a cross-sectional view of the FIG. 2B structure following completion of the epitaxial growth of crystalline source/drain regions having defects, according to an embodiment of the invention.

FIG. 3A shows a cross-sectional view of a semiconductor structure following epitaxial growth of crystalline source/drain regions having defects, according to an embodiment of the invention.

FIG. 3B shows a cross-sectional view of the FIG. 3A structure following an amorphizing implantation process which converts the crystalline source/drain regions to an amorphous material, according to an embodiment of the invention.

FIG. 3C shows a cross-sectional view of the FIG. 3B structure following a recrystallization process that converts the amorphous material to stressed crystalline source/drain regions, according to an embodiment of the invention.

FIG. 4 shows a cross-sectional view of a structure illustrating a stress profile induced in nanosheet channel layers by stressed crystalline sourced/drain regions, according to an embodiment of the invention.

FIG. 5 shows an integrated circuit comprising one or more semiconductor structures with stressed nanosheet channels, according to an embodiment of the invention.

### DETAILED DESCRIPTION

Illustrative embodiments of the invention may be described herein in the context of illustrative methods for forming semiconductor structures with stressed nanosheet channels, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

As described above, the use of stacked nanosheet channels provide techniques useful for reducing the size of field-effect transistors (FETs). A FET is a transistor having a source, a gate, and a drain, and having action that depends on the flow of majority carriers along a channel that runs past the gate between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Increasing demand for high density and performance in integrated circuit devices requires development of new structural and design features, including shrinking gate lengths and other reductions in size or scaling of devices. Continued scaling, however, is reaching limits of conventional fabrication techniques. An important indicator of device performance is carrier mobility. It is difficult to keep carrier mobility high as devices continue to shrink in size.

Current carrying capability, and thus performance of a FET, may be considered proportional to the mobility of a majority carrier in the channel. The mobility of holes (e.g., the majority carriers in a pFET) and the mobility of electrons (e.g., the majority carriers in an nFET) can be enhanced by applying an appropriate stress to the channel. Stress engineering methods may be used to enhance performance, increasing device drive current without increasing device size or capacitance. Application of a tensile stress (in a longitudinal direction) to nFETs enhances electron mobility, while application of compressive stress (in the longitudinal direction) to pFETs enhances hole mobility.

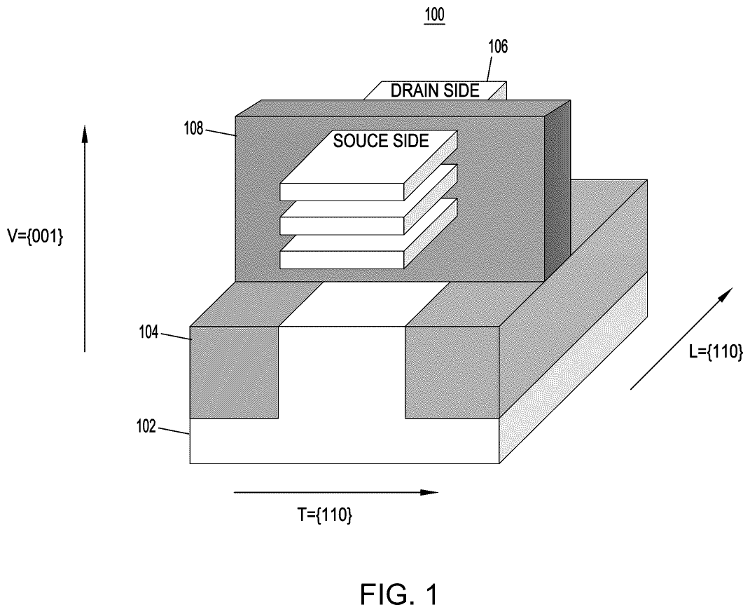

Nanosheet transistors benefit from the same stress tensors as planar transistor devices. FIG. 1, for example, shows a semiconductor structure 100 including a substrate 102, shallow trench isolation (STI) regions 104, nanosheet channel layers 106, and a gate 108. In FIG. 1, the nanosheet channel layers 106 extend to either side of the gate 108 (e.g., to a source side and a drain side), though in the final structure the nanosheet channel layers 106 will not be present in such regions and source/drain regions will be formed instead. FIG. 1 also labels the longitudinal (L), transverse (T) and vertical (V) directions which benefit from stress tensors, with their associated crystal structures including L={110), T={110}, V={001}. For a pFET nanosheet transistor, compressive stress is beneficial in the longitudinal direction, while tensile stress is beneficial in the transverse and vertical directions.

As illustrated in FIG. 1, no bulk silicon (Si) or cladded Si is present to template from in the longitudinal direction, so there is no stress in the longitudinal direction. Silicon germanium (SiGe) material that is grown (e.g., for the source/drain regions) from the sides of the nanosheet channel layers 106 will have no longitudinal stress, but will have vertical stress given the lattice mismatch. SiGe material that is grown (e.g., for the source/drain regions) from the bottom (e.g., the top surface of the substrate 102) will have longitudinal stress. However, since SiGe is grown from both the bottom (e.g., the top surface of the substrate 102) and the sides (e.g., of the nanosheet channel layers 106), there is a large number of stacking faults and defects reducing the longitudinal stress significantly. SiGe material provides value in terms of stressing nanosheet channels when used as a source/drain epitaxial layer for pFET nanosheet devices.

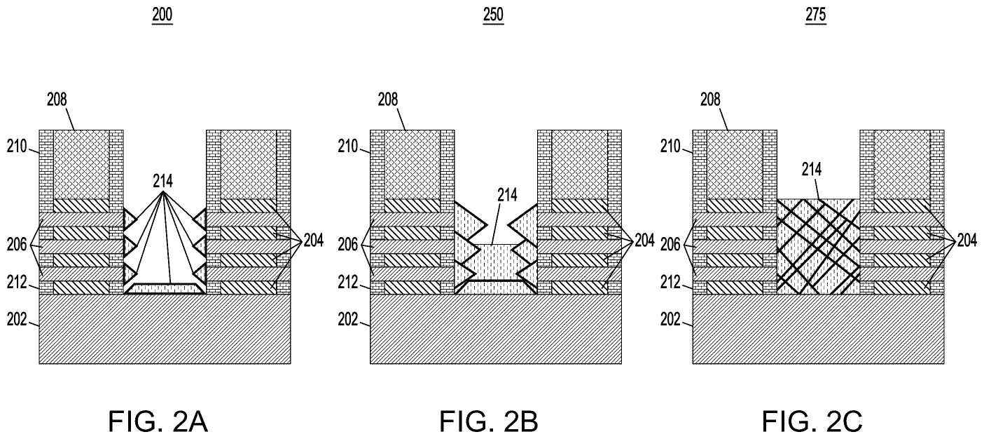

FIGS. 2A-2C illustrate a process flow for epitaxial growth of source/drain regions for nanosheet transistor devices. FIG. 2A shows a cross-sectional view 200 of a structure including a substrate 202 and a nanosheet stack including sacrificial layers 204 and nanosheet channel layers 206. The substrate 202 and nanosheet channel layers 206 may both be formed of Si, and the sacrificial layers 204 may be formed of SiGe. The structure also includes dummy gate structures 208, gate spacers 210 and inner spacers 212. An epitaxial growth process is used to grow source/drain regions above the exposed portion of the substrate 202 (e.g., between the sacrificial layers 204, the nanosheet channel layers 206, the inner spacers 212, the gate spacers 210 and the dummy gate structures 208). The epitaxial growth process has seven fronts—the top surface of the substrate 202 as well as the exposed surfaces of each of the six nanosheet channel layers 206. FIG. 2A shows the initial growth of epitaxial layer 214 from these seven fronts. FIG. 2B shows a cross-sectional view 250 of the structure of FIG. 2A as the epitaxial growth process continues, resulting in continued formation of the epitaxial layer 214 with defects and stacking faults (illustrated by the thick bold lines in FIG. 2B). FIG. 2C shows a cross-sectional view 275 of the structure of FIG. 2B following conclusion of the epitaxial growth process, where the resulting epitaxial layer 214 providing source/drain regions is defective (e.g., with numerous stacking faults) and is fully relaxed. It is extremely challenging to obtain any significant amount of strain in the nanosheet channel layers 206 with such an epitaxial growth process for the source/drain regions, thus conventional approaches will not lead to stress in source/drain epitaxial regions in nanosheet transistor technology.

Illustrative embodiments provide techniques for forming semiconductor structures with stressed nanosheet channels. In some embodiments, source/drain regions are formed in the semiconductor structures, where the source/drain regions provide a stressor material for achieving a desired type of longitudinal stress in nanosheet channel layers (e.g., compressive for pFETs, tensile for nFETs).

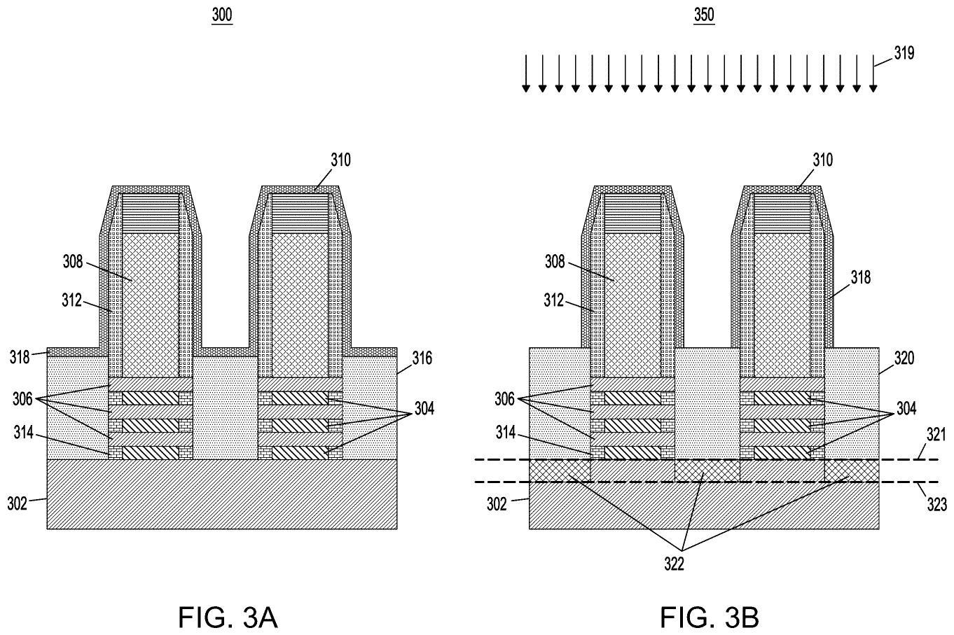

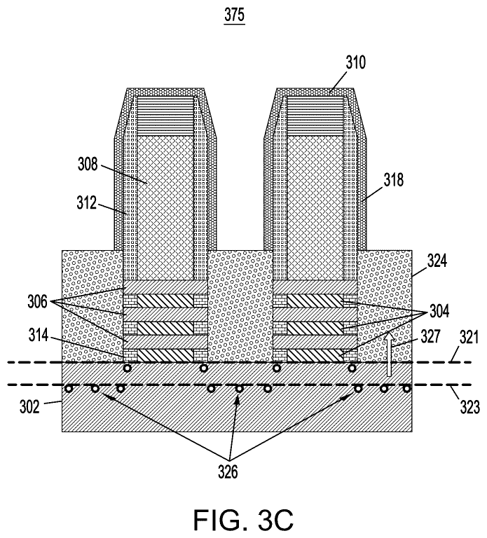

FIGS. 3A-3C show a process flow for forming semiconductor structures with stressed nanosheet channel layers. FIG. 3A shows a cross-sectional view 300 of a semiconductor structure including a substrate 302, sacrificial layers 304, nanosheet channel layers 306, dummy gate structures 308, hard mask 310, gate spacers 312, inner spacers 314, epitaxial layers 316, and encapsulation layer 318.

The substrate 302 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. The substrate 102 may have a height and width which vary as needed based on the type of structures to be formed.

The sacrificial layers 304 may be formed of SiGe. Each of the sacrificial layers 304 may have a thickness in the range of 5-15 nm.

The nanosheet channel layers 306 will provide channels for transistors in a transistor structure (e.g., nanosheet transistors in a nanosheet transistor structure). The nanosheet channel layers 306 may be formed of Si or another suitable material (e.g., a material similar to that used for the substrate 302). Each of the nanosheet channel layers 306 may have a thickness in the range of 5-15 nm.

The dummy gate structures 308 may be formed of amorphous silicon (a-Si), amorphous silicon germanium (a-SiGe) over a thin SiO₂ or titanium nitride (TiN) layer, or another suitable material.

The hard mask 310 may be formed of silicon nitride (SiN), a multi-layer of SiN and SiO₂, or another suitable material.

The gate spacers 312 may be formed of silicon boron carbide nitride (SiBCN) or another suitable material such as SiN, SiOC, silicon oxycarbonitride (SiOCN), etc.

The inner spacers 314 may be formed of SiN, SiBCN, SiOCN, SiOC, or another suitable material.

The epitaxial layers 316 may be formed of SiGe or another suitable material.

The encapsulation layer 318 may be formed of SiN, SiBCN, SiOCN, SiOC or another suitable material. The encapsulation layer 318 may also be referred to as an insulation liner.

The semiconductor structure of FIG. 3A may be formed by depositing the nanosheet stack (e.g., the sacrificial layers 304 and the nanosheet channel layers 306) over the substrate 302. The nanosheet stack may then be patterned (e.g., using lithographic processing), followed by fill and recess of material (e.g., silicon dioxide (SiO₂), silicon oxycarbide (SiOC), silicon oxynitride (SiON), etc.) for shallow trench isolation (STI) regions (not shown in FIG. 3A). The dummy gate structures 308 are then patterned using the hard mask 310. Material for the gate spacers 312 is then formed. An indent etch is then performed to indent the sacrificial layers 304. The inner spacers 314 are then formed in the indent regions. The depth of the indent etch may be in the range of 5-9 nm. The epitaxial layers 316 may be formed using an epitaxial growth process similar to that described above with respect to FIGS. 2A-2C, which results in the epitaxial layers 316 being unstressed, and having defects and stacking faults. nFET portions of the epitaxial layers 316 may be made of carbon-doped silicon (Si:C), which is further doped with an n-type dopant such as phosphorus (P), such that the nFET portions of the epitaxial layers 316 are Si:C doped with P. pFET portions of the epitaxial layers 316 may be made of SiGe, which is doped with a p-type dopant such as boron (B), such that the pFET portions of the epitaxial layers 316 are SiGe:B. The encapsulation layer 318 is then formed over the structure.

As shown in the cross-sectional view 350 of FIG. 3B, the structure of FIG. 3A is then subject to an amorphizing implantation process 319. Prior to the amorphizing implantation process 319, one or more portions of the structure of FIG. 3A may be blocked. In the description below, it is assumed that the amorphizing implantation process 319 is used to form amorphized regions of the epitaxial layers 316 for pFETs, where the portions of the structure of FIG. 3A where nFETs are formed will be blocked. It should be appreciated, however, that in other embodiments the amorphizing implantation process 319 may be used to form amorphized regions of the epitaxial layers 316 for nFETs, though different implants will be used. It should further be appreciated that multiple amorphizing implantation processes may be used (e.g., one for pFETs, one for nFETs).

The amorphizing implantation process 319 amorphizes the epitaxial layers 316 and a portion of the underlying substrate 302 below the epitaxial layers 316, shown in FIG. 3B as amorphized epitaxial layers 320 and amorphized substrate regions 322. FIG. 3B also shows boundary lines 321 and 323. The boundary line 321 illustrates the boundary between the amorphized epitaxial layers 320 (e.g., formed of amorphous SiGe (a-SiGe)) and the amorphized substrate regions 322 (e.g., formed of a-Si). The boundary line 323 illustrates the boundary between the amorphized substrate regions 322 and the un-amorphized substrate 302. Here, the gate height of the dummy gate structures 308 protects the nanosheet channel layers 306 from being amorphized during the amorphizing implantation process 319.

The amorphizing implantation process 319 may include one or more implant processes that can be tailored to amorphize to the right depth within the substrate 302 (e.g., below the boundary line 321 down to the boundary line 323). The amorphizing implantation process 319 is designed to occur close to but below the boundary line 321 (e.g., the SiGe/Si interface). The depth or distance between the boundary lines 321 and 323 may be in the range of 0 to 50 nm, to template from the Si. Alternatively, the amorphizing implantation process 319 may be designed to be above the boundary line 321 by a small amount, if the SiGe of the epitaxial layers 316 retain some stress. The implant conditions of the amorphizing implantation process 319 may be tailored with suitable elements or compounds (e.g., with Ge, Si, boron difluoride (BF₂), etc. for pFETs, carbon (C) for nFETs, etc.).

The amorphizing implantation process 319 may be performed without causing damage to the nanosheet channel layers 306 through tailoring the implant conditions appropriately, such as by performing a room temperature or colder (e.g., from 200 kelvin (K) down to about 77K) implant. In some embodiments, a double Ge implant is used, with varying energies. The energies of the implant will vary based on factors such as the material, its thickness, the concentration of Ge in the source/drain regions, the implantation dose, etc. In some embodiments, energies ranging from 50 to 300 kiloelectron volts (keV) are used for the first deep implant, followed by energies of 1 to 50 keV for the following shallow implant, with doses varying from 1e13 to 4e14. These implant conditions are aimed at preventing damage to the nanosheet channel layers 306 while achieving a complete amorphization of the source and drain regions.

FIG. 3C shows a cross-sectional view 375 of the structure of FIG. 3B following a recrystallization process, such as a solid phase epitaxial regrowth (SPER) process. The recrystallization process transforms the amorphized substrate regions 322 back to crystalline substrate 302, though there are detectable end-of-range damage structures 326 at the former interfaces between the substrate 302 and the amorphized substrate regions 322. The recrystallization includes anneal templates 327 from the boundary line 323 up to the boundary line 321 and through the amorphized epitaxial layers 320, which become stressed crystalline epitaxial layers 324. The stressed crystalline epitaxial layers 324 advantageously provide longitudinal stress in the nanosheet channel layers 306.

The recrystallization temperature and time anneal of the SPER process for epitaxial recrystallization of a-SiGe in the solid phase is designed to allow for much faster growth of {100} crystalline SiGe. Templating from the sidewalls of the nanosheet channel layers 306 should be relatively small if the rate of formation of {110} crystalline SiGe is less than the rate of formation of {001} crystalline SiGe (e.g., r{110}<0.3 r{001}). When the SiGe templates from the Si below in the substrate 302, the SiGe is stressed in compression. Thermal treatment will cause a transfer of longitudinal stress to the nanosheet channel layers 306. When the channel release (e.g., removal of the sacrificial layers 304) is performed, the stress transfer is even larger when the structure is exposed to thermal treatment. The larger stress transfer is a result of having the nanosheet channel layer 306 exposed to air/vacuum on the top and bottom, rather than being bound with a SiGe material (e.g., the sacrificial layers 304). The SPER sequence advantageously includes faster growth from the bottom up (e.g., from the boundary line 323 up to the boundary line 321 and through the amorphized epitaxial layers 320). The process of converting fully amorphized epitaxial layers 320 with SPER results in substantially less defectivity (e.g., relative to the process shown in FIGS. 2A-2C) and significantly increased stress. Constrained growth can further potentially facilitate better small diamond merges and better crystallinity in the stressed crystalline epitaxial layers 324.

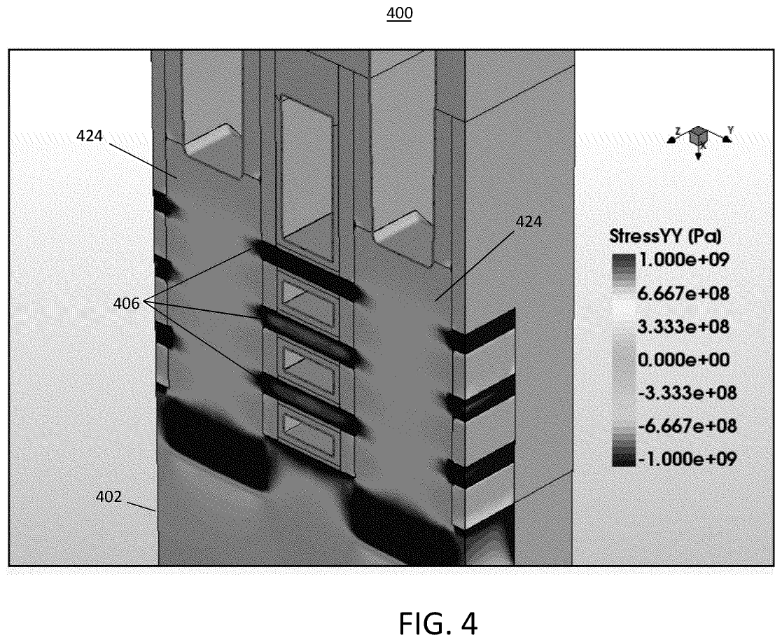

FIG. 4 shows a cross-sectional view 400 of a structure having a substrate 402, nanosheet channel layers 406, and source/drain regions 424, where the substrate 402, nanosheet channel layers 406 and source/drain regions 424 are formed in a manner similar to that described above with respect to substrate 302, nanosheet channel layers 306 and the stressed crystalline epitaxial layers 324, respectively. FIG. 4 further shows a stress profile (e.g., Stress YY in the Y-direction), illustrating longitudinal stress that is induced in the nanosheet channel layers 406 by the stressed crystalline material of the source/drain regions 424.

In some embodiments, source/drain regions for nanosheet transistor structures are formed where the source/drain regions include a material (e.g., SiGe) which is substantially strained (e.g., in compression for pFETs, tension for nFETs) in the longitudinal direction of current flow along nanosheet channel layers. The structures may include a substrate (e.g., formed of Si) and source/drain regions (e.g., formed of SiGe for pFETs) over the substrate, with an interface including end-of-range (EOR) damage structures in the substrate below the source/drain regions. Further, the source/drain regions provide stress transfer to nanosheet channel layers of nanosheet transistor devices. Such structures may be formed by forming epitaxial layers for the source/drain regions (e.g., with defects and stacking faults), followed by amorphization (e.g., of SiGe for pFETs), followed by SPER recrystallization with fastest {001} crystalline growth rates to template the crystallization in the source/drain regions from the substrate below the source/drain regions (e.g., rather than from the nanosheet channel layers adjacent the source/drain regions). If the stress is sufficiently high, then the nanosheet channel layers, upon channel release, may bend or buckle (e.g., depending on the channel length). To counter this, some columns of the sacrificial layers (e.g., formed of SiGe) may be left intact during the channel release. Advantageously, the resulting structures have significant carrier mobility improvement from longitudinal compressive (for pFETs) or tensile (for nFETs) stress.

According to an aspect of the invention, a semiconductor structure includes a substrate, two or more nanosheet channel layers disposed over a first portion of the substrate, and a source/drain region disposed over a second portion of the substrate adjacent the first portion of the substrate. The source/drain region is a crystalline semiconductor material which transfers a longitudinal stress to the two or more nanosheet channel layers.

In embodiments, the second portion of the substrate below the source/drain region has an interface with end-of-range damage structures. The interface may be a distance below a top surface of the substrate adjacent the source/drain region. The end-of-range damage structures may be produced during a recrystallization process that converts an amorphous semiconductor material to the crystalline semiconductor material. The end-of-range damage structures may include a border of amorphous semiconductor material in the substrate surrounded by crystalline semiconductor material.

In embodiments, the two or more nanosheet channel layers provide channels for a p-type nanosheet transistor, and the crystalline semiconductor material of the source/drain region transfers a compressive longitudinal stress to the two or more nanosheet channel layers. The crystalline semiconductor material may be SiGe or SiGe:B.

In embodiments, the two or more nanosheet channel layers provide channels for an n-type nanosheet transistor, and the crystalline semiconductor material of the source/drain region transfers a tensile longitudinal stress to the two or more nanosheet channel layers. The crystalline semiconductor material may be Si:C, which is further doped with P.

In embodiments, the semiconductor structure further includes one or more columns of a sacrificial material disposed between adjacent ones of the two or more nanosheet channel layers.

According to an aspect of the invention, a semiconductor structure includes a substrate, two or more nanosheet channel layers disposed over a first portion of the substrate, a first source/drain region disposed over a second portion of the substrate adjacent a first side of the first portion of the substrate, and a second source/drain region disposed over a third portion of the substrate adjacent a second side of the first portion of the substrate, where the first source/drain region and the second source/drain region provide a stressor material which transfers a longitudinal stress to the two or more nanosheet channel layers.

In embodiments, the stressor material is a semiconductor material with a {001} crystalline orientation. The two or more nanosheet channel layers may provide channels for a p-type nanosheet transistor, and the stressor material may be SiGe or SiGe:B. The two or more nanosheet channel layers may alternatively provide channels for an n-type nanosheet transistor, and the stressor material may be Si:C.

In embodiments, the second portion of the substrate and the third portion of the substrate have an interface with end-of-range damage structures a distance below a top surface of the substrate adjacent the first source/drain region and the second source/drain region.

In embodiments, the two or more nanosheet channel layers are a first semiconductor material, and the semiconductor structure further includes one or more columns of a second semiconductor material disposed between a first one of the two or more nanosheet channel layers and a second one of the two or more nanosheet channel layers.

According to an aspect of the invention, an integrated circuit includes a semiconductor structure including a substrate, two or more nanosheet channel layers disposed over a first portion of the substrate, and a source/drain region disposed over a second portion of the substrate adjacent the first portion of the substrate. The source/drain region is a crystalline semiconductor material which transfers a longitudinal stress to the two or more nanosheet channel layers.

In embodiments, the second portion of the substrate below the source/drain region has an interface with end-of-range damage structures.

In embodiments, the two or more nanosheet channel layers provide channels for a p-type nanosheet transistor, and the crystalline semiconductor material of the source/drain regions transfers a compressive longitudinal stress to the two or more nanosheet channel layers.

In embodiments, the two or more nanosheet channel layers provide channels for an n-type nanosheet transistor, and the crystalline semiconductor material of the source/drain region transfers a tensile longitudinal stress to the two or more nanosheet channel layers.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

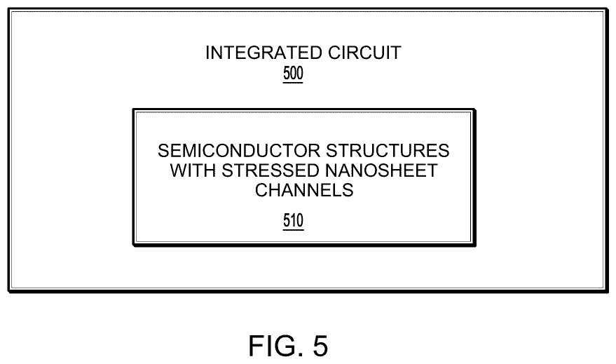

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 5 shows an example integrated circuit 500 which includes one or more semiconductor structures 510 with stressed nanosheet channels.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a substrate;
two or more nanosheet channel layers disposed over a first portion of the substrate; and
a source/drain region disposed over a second portion of the substrate adjacent the first portion of the substrate, the source/drain region comprising a crystalline semiconductor material which transfers a longitudinal stress to the two or more nanosheet channel layers.

2. The semiconductor structure of claim 1, wherein the second portion of the substrate below the source/drain region comprises an interface with end-of-range damage structures.

3. The semiconductor structure of claim 2, wherein the interface is a distance below a top surface of the substrate adjacent the source/drain region.

4. The semiconductor structure of claim 2, wherein the end-of-range damage structures are produced during a recrystallization process that converts an amorphous semiconductor material to the crystalline semiconductor material.

5. The semiconductor structure of claim 2, wherein the end-of-range damage structures comprise a border of amorphous semiconductor material in the substrate surrounded by the crystalline semiconductor material.

6. The semiconductor structure of claim 1, wherein the two or more nanosheet channel layers provide channels for a p-type nanosheet transistor, and wherein the crystalline semiconductor material of the source/drain region transfers a compressive longitudinal stress to the two or more nanosheet channel layers.

7. The semiconductor structure of claim 6, wherein the crystalline semiconductor material comprises silicon germanium.

8. The semiconductor structure of claim 6, wherein the crystalline semiconductor material comprises boron-doped silicon germanium.

9. The semiconductor structure of claim 1, wherein the two or more nanosheet channel layers provide channels for an n-type nanosheet transistor, and wherein the crystalline semiconductor material of the source/drain region transfers a tensile longitudinal stress to the two or more nanosheet channel layers.

10. The semiconductor structure of claim 9, wherein the crystalline semiconductor material comprises carbon-doped silicon.

11. The semiconductor structure of claim 9, wherein the crystalline semiconductor material comprises carbon-doped silicon that is further doped with phosphorus.

12. A semiconductor structure comprising:
a substrate;
two or more nanosheet channel layers disposed over a first portion of the substrate;
a first source/drain region disposed over a second portion of the substrate adjacent a first side of the first portion of the substrate;
a second source/drain region disposed over a third portion of the substrate adjacent a second side of the first portion of the substrate;
wherein the first source/drain region and the second source/drain region comprise a stressor material which transfers a longitudinal stress to the two or more nanosheet channel layers.

13. The semiconductor structure of claim 12, wherein the stressor material comprises a semiconductor material with a {001} crystalline orientation.

14. The semiconductor structure of claim 13, wherein the two or more nanosheet channel layers provide channels for a p-type nanosheet transistor, and wherein the stressor material comprises boron-doped silicon germanium.

15. The semiconductor structure of claim 13, wherein the two or more nanosheet channel layers provide channels for an n-type nanosheet transistor, and wherein the stressor material comprises carbon-doped silicon.

16. The semiconductor structure of claim 12, the second portion of the substrate and the third portion of the substrate comprise an interface with end-of-range damage structures a distance below a top surface of the substrate adjacent the first source/drain region and the second source/drain region.

17. An integrated circuit comprising:
a semiconductor structure comprising:
a substrate;
two or more nanosheet channel layers disposed over a first portion of the substrate; and
a source/drain region disposed over a second portion of the substrate adjacent the first portion of the substrate, the source/drain region comprising a crystalline semiconductor material which transfers a longitudinal stress to the two or more nanosheet channel layers.

18. The integrated circuit of claim 17, wherein the second portion of the substrate below the source/drain region comprises an interface with end-of-range damage structures.

19. The integrated circuit of claim 17, wherein the two or more nanosheet channel layers provide channels for a p-type nanosheet transistor, and wherein the crystalline semiconductor material of the source/drain region transfers a compressive longitudinal stress to the two or more nanosheet channel layers.

20. The integrated circuit of claim 17, wherein the two or more nanosheet channel layers provide channels for an n-type nanosheet transistor, and wherein the crystalline semiconductor material of the source/drain region transfers a tensile longitudinal stress to the two or more nanosheet channel layers.
